(19) United States
(12) Patent Application Publication
(10) Pub. No.: US 2014/0084416 A1
(43) Pub. Date: Mar. 27, 2014

(54) Stacked Package and Method of Manufacturing the Same

(71) Applicant: Tae-Ho Kang, Seoul (KR)

(72) Inventor: Tae-Ho Kang, Seoul (KR)

(21) Appl. No.: 13/943,949

(22) Filed: Jul. 17, 2013

(30) Foreign Application Priority Data
Sep. 25, 2012 (KR) 10-2012-0106333

(51) Int. Cl. H01L 23/498

(52) U.S. Cl. CPC H01L 23/49811
USPC 257/532

(57) ABSTRACT

A stacked package includes a first package substrate having a major surface that defines a horizontal plane, first pads on an upper portion of the first package substrate, a multilayer capacitor on the first pads, and a first semiconductor chip on the first package substrate. A second package substrate is provided on the first semiconductor package, and a second semiconductor chip is on the second package substrate. Conductive bumps are provided between the first package substrate and the second package substrate that are vertically aligned with the multilayer capacitor. Signal characteristics in the stacked package may be improved by the multilayer capacitor. Because the multilayer capacitor is formed in the stacked package it may provide for an increased degree of integration.

### CROSS-REFERENCE TO RELATED APPLICATION

This application claims priority under 35 U.S.C. §119 to Korean Patent Application No. 10-2012-0106333, filed on Sep. 25, 2012 in the Korean Intellectual Property Office (KIPO), the contents of which are incorporated herein by reference in their entirety.

### BACKGROUND

A stacked package, in which a plurality of packages are stacked, has been used to increase the degree of integration of a semiconductor package.

Various circuit elements and wirings may be arranged on a main board of an electronic device. A stacked package may be mounted on the main board. As the integration of the circuit elements and wirings is increased, these circuit elements and/or wirings may act as inductors, which may degrade the characteristics of signals transmitted through the main board and/or the stacked package due to, for example, increased impedance and/or signal overshoot at high frequencies. Accordingly, a multilayer ceramic capacitor (MLCC) may be mounted on the main board to improve the signal characteristics.

### SUMMARY

Example embodiments provide a stacked package that may have improved signal characteristics.

Example embodiments provide a method of manufacturing a stacked package that may have improved signal characteristics.

According to example embodiments, a stacked package is provided. The stacked package includes a first package substrate and a second package substrate. A first semiconductor chip is on the first package substrate thereon. A multilayer capacitor is also on the first package substrate spaced apart from the first semiconductor chip. A molding member is also on the first package substrate and covers at least a portion of the first semiconductor chip. The second package substrate is arranged over the first package substrate and is electrically connected thereto. first pads and a plurality of second pads at upper portions thereof. First conductive bumps may be provided on the plurality of first pads.

In example embodiments, the multilayer capacitor includes first and second external electrodes that may be electrically connected to respective first and second of the plurality of second pads.

In example embodiments, the stacked package may further include second conductive bumps on at least upper surfaces of the first and second external electrodes.

In example embodiments, the second conductive bumps may be on upper sidewalls of the first and second external electrodes.

In example embodiments, the second package substrate has a second semiconductor chip thereon and third and fourth pads at lower portions thereof. The first conductive bumps may be electrically connected to the third pads, and the second conductive bumps may be electrically connected to contact the fourth pads.

In example embodiments, the first to the fourth pads may have a conductive material.

In example embodiments, some of the second pads may include a conductive material, and the others of the second pads may include an insulating material. Some of the fourth pads may include a conductive material, and the others of the fourth pads may include an insulating material.

In example embodiments, all of the second pads may include a conductive material, and all of the fourth pads may include an insulating material.

In example embodiments, the stacked package may further include a plurality of fifth pads between the multilayer capacitor and the second pads, respectively.

In example embodiments, a recess may be formed on the first package substrate. The first package substrate may include first pads at upper portions of the first package substrate where the recess is not formed and second pads on the recess. First conductive bumps may be formed on the first pads, and the multilayer capacitor may be formed on the second pads.

According to example embodiments, there is provided a stacked package. The stacked package includes a first semiconductor package, a second semiconductor package and second conductive bumps. The first semiconductor package includes a first package substrate having a recess thereon, first pads on the recess, a multilayer capacitor on the first pads and a first semiconductor chip mounted on the first package substrate. The second semiconductor package arranged over the first semiconductor package includes a second package substrate including second pads at lower portions thereof and a second semiconductor chip mounted on the second package substrate. Each second conductive bump makes contact with the multilayer capacitor and one of the second pads.

In example embodiments, the first semiconductor package may further include a molding member on the first package substrate to cover at least a portion of the first semiconductor chip.

According to example embodiments, there is provided a stacked package. The stacked package includes a first package substrate and a second package substrate. The first package substrate has a first semiconductor chip on a central top surface thereof. A plurality of conductive bumps are provided on the first package substrate arranged around the first semiconductor chip and at least one multilayer capacitor is provided on the first package substrate adjacent to the conductive bumps. A distance between the at least one multilayer capacitor and the conductive bumps adjacent thereto is substantially the same as a distance between the conductive bumps. The second package substrate is arranged over the first package substrate and is electrically connected to the first package substrate via the conductive bumps and the multilayer capacitor.

According to example embodiments, there is provided a method of manufacturing a stacked package. In the method, conductive bumps and a multilayer capacitor are formed on a first package substrate including a first semiconductor chip mounted thereon. A molding member is formed on the first package substrate to cover at least a portion of the first semiconductor chip, the first conductive bumps and the multilayer capacitor. The molding member is partially removed to form an opening exposing the first conductive bumps and at least an upper surface of the multilayer capacitor. Second and third bumps are formed on a bottom surface of a second package substrate having a second semiconductor chip mounted thereon. The first and the second conductive bumps, and the multilayer capacitor and the third conductive bumps are bonded, respectively.

In example embodiments, the first package substrate may include first and second pads at upper portions thereof, and the second package substrate may include third and fourth pads at lower portions thereof. When the conductive bumps and the multilayer capacitor are formed on the first package substrate, the first conductive bumps and the multilayer capacitor may be formed on the first and the second pads, respectively. When the second and third bumps are formed on the lower portion of the second package substrate, the second and the third conductive bumps may be formed on the third and the fourth pads, respectively.

A stacked package in accordance with example embodiments may include the multilayer capacitor by which some of conductive bumps are replaced, and the conductive bumps may connect the first semiconductor package with the second semiconductor package. Thus, signal characteristics in the stacked package may be improved. Additionally, because there is no need of the additional space for forming the multilayer capacitor, the method of manufacturing the stacked package in accordance with example embodiments may be more advantageous than forming the multilayer capacitor on a main board having the stack package mounted thereon in the aspect of the high integration degree.

A stacked package in accordance with example embodiments may include a first package substrate having a major surface that defines a horizontal plane, first pads on an upper portion of the first package substrate, a multilayer capacitor on the first pads, and a first semiconductor chip on the first package substrate. A second package substrate is provided on the first semiconductor package, and a second semiconductor chip is on the second package substrate. Conductive bumps are provided between the first package substrate and the second package substrate that are vertically aligned with the multilayer capacitor.

In example embodiments, second pads may be provided on a lower portion of the second package substrate that are vertically aligned with the multilayer capacitor.

In example embodiments, the conductive bumps may comprise first conductive bumps, and the stacked package may further include third pads on the upper portion of the first package substrate, fourth pads on the lower portion of the second package substrate, and second conductive bumps that electrically connect respective ones of the third pads to respective ones of the fourth pads.

In example embodiments, a molding member may be provided on the first package substrate that covers at least a portion of the first semiconductor chip. The first and second conductive bumps may penetrate the molding member.

In example embodiments, at least one of the first pads, at least one of the second pads, at least one of the second the conductive bumps and the multilayer capacitor may provide a signal path between the first and second package substrates.

In example embodiments, the first package substrate may include a recessed region, and the first pads may be within the recessed region.

In example embodiments, the multilayer capacitor may have first and second external electrodes, and one of the first pads, the first external electrode, one of the first conductive bumps and one of the second pads may be vertically aligned, and another of the first pads, the second external electrode, another of the first conductive bumps and another of the second pads may be vertically aligned.

In example embodiments, at least one of the first pads or one of the second pads that are vertically aligned with the multilayer capacitor may comprise an insulating material.

### BRIEF DESCRIPTION OF THE DRAWINGS

Example embodiments will be more clearly understood from the following detailed description taken in conjunction with the accompanying drawings. FIGS. 1 to 17 represent non-limiting, example embodiments as described herein.

FIG. 1 is a cross-sectional view illustrating stacked packages in accordance with example embodiments.

FIGS. 2 and 3 are plan views of first semiconductor packages included in the stacked packages in accordance with example embodiments.

FIGS. 4 and 5 are cross-sectional views illustrating stacked packages in accordance with example embodiments.

FIGS. 6 to 11 are cross-sectional views illustrating stages of a method of manufacturing a stacked package in accordance with example embodiments.

FIG. 12 is a cross-sectional view illustrating a stacked package in accordance with example embodiments.

FIG. 13 is a cross-sectional view illustrating a stacked package in accordance with example embodiments.

FIG. 14 is a cross-sectional view illustrating a stacked package in accordance with example embodiments.

FIG. 15 is a cross-sectional view illustrating a stacked package in accordance with example embodiments.

FIGS. 16 and 17 are cross-sectional views illustrating a stacked package in accordance with example embodiments.

### DETAILED DESCRIPTION OF THE EMBODIMENTS

Various example embodiments will be described more fully hereinafter with reference to the accompanying drawings, in which some example embodiments are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

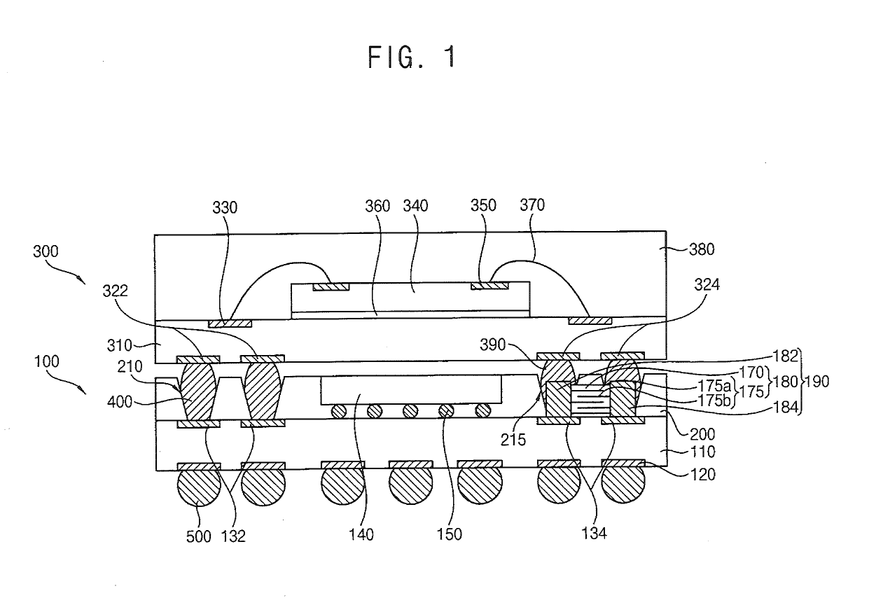

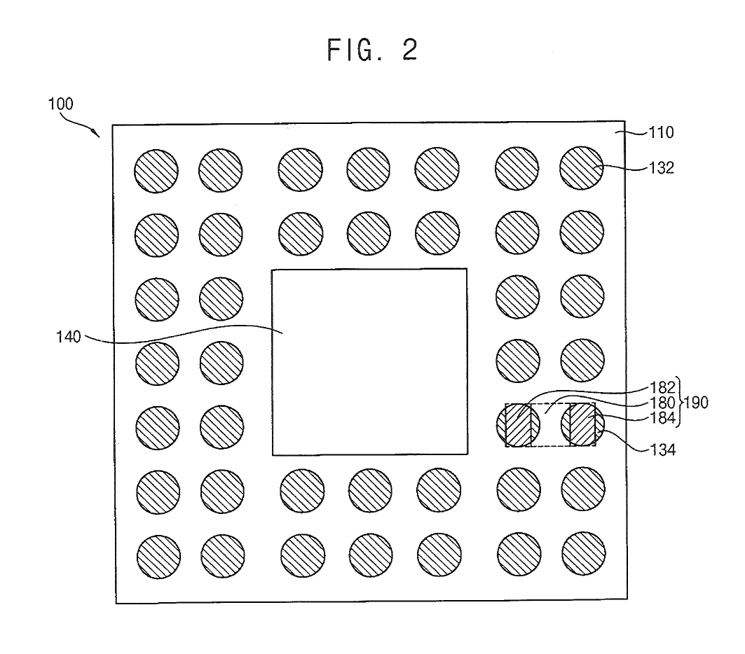

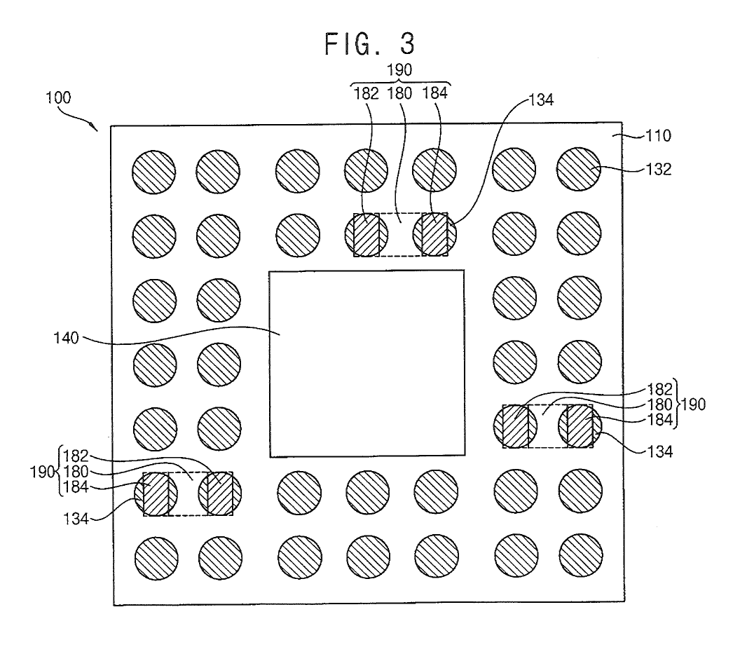

FIGS. 1, 4 and 5 are cross-sectional views illustrating stacked packages in accordance with example embodiments, and FIGS. 2 and 3 are plan views of first semiconductor packages included in the stacked packages in accordance with example embodiments.

Referring to FIGS. 1 and 2, the stacked package may include a first semiconductor package 100, a second semiconductor package 300, and third and fourth conductive bumps 390 and 400.

The first semiconductor package 100 may include a first package substrate 110, a first semiconductor chip 140, a multilayer capacitor 190 and a first molding member 200.

The first package substrate 110 may be, for example, a printed circuit board (PCB) and may have first to third pads 120, 132 and 134. The first package substrate 110 may further include various wirings (not shown) which may be electrically connected to the first to third pads 120, 132 and 134. The first to third pads 120, 132, 134 may comprise, for example, contact pads.

In example embodiments, a plurality of first pads 120 may be formed at lower portions of the first package substrate 110, and bottom surfaces of the first pads 120 may be exposed.

In example embodiments, the second and third pads 132 and 134 may be formed at upper portions of the first package substrate 110 and may be spaced apart from the first semiconductor chip 140. Top surfaces of the second and third pads 132 and 134 may be exposed. In FIG. 2, the second and third pads 132 and 134 are shown to be arranged at regular intervals, and two third pads 134 are provided that are adjacent each other. However, the arrangement and the number of the second and third pads 132 and 134 are not limited thereto. For example, a plurality of third pads 134 such as four, six, or eight third pads 134 may be formed. A total of six third pads 134 are shown in the example embodiment of FIG. 3. In some embodiments, at least some of the third pads 134 may be arranged as pairs of third pads, with two adjacent pads 134 forming each pair.

The first to third pads 120, 132 and 134 may include a conductive material, for example, a metal.

The first semiconductor chip 140 may be mounted on the first package substrate 110. For example, as shown in FIGS. 2 and 3, the first semiconductor chip 140 may be mounted on a central top surface of the first package substrate 110.

In example embodiments, the first semiconductor chip 140 may be attached to the top surface of the first package substrate 110 using first conductive bumps 150. The first conductive bumps 150 may, for example, include solder balls. In other embodiments, the first semiconductor chip 140 may be attached to the first package substrate 110 using an adhesive layer (not shown) or other attachment mechanisms.

The first semiconductor chip 140 may include an application processor (AP) chip, a logic chip, etc.

The multilayer capacitor 190 may be, for example, a multilayer ceramic capacitor (MLCC). Thus, the multilayer capacitor 190 may include a capacitor body 180, and first and second external electrodes 182 and 184.

The capacitor body 180 may include a dielectric layer 170 and a plurality of stacked internal electrodes 175 therein.

The dielectric layer 170 may have, for example, a rectangular parallelepiped shape. The rectangular parallelepiped shape may have four lateral surfaces that are substantially perpendicular to the top surface of the first package substrate 110, and two of the lateral surfaces, e.g., first and second lateral surfaces may be opposite to each other, and the other two of the lateral surfaces, e.g., third and fourth lateral surfaces may be opposite to each other and substantially perpendicular to the first and second lateral surfaces. In example embodiments, the dielectric layer 170 may include a binder, various types of additives, and a ceramic material, e.g., barium titanate, titanium oxide, etc.

Each internal electrode 175 may have, for example, a flat plate shape and may be substantially parallel to the top surface of the first package substrate 110. In one example embodiment, the internal electrodes 175 may include first internal electrodes 175a and second internal electrodes 175b. The first internal electrode 175a may have one end portion exposed at the first lateral surface and the other end portion at an inside of the dielectric layer 170, and the second internal electrode 175b may have one end portion exposed at the second lateral surface and the other end portion at the inside of the dielectric layer 170. The first and second internal electrodes 175a and 175b may be alternately stacked in the dielectric layer 170 along a direction that is substantially perpendicular to the top surface of the first package substrate 110. An electrical capacity of the multilayer capacitor 190 may depend on, among other things, the number of internal electrodes 175 stacked within the dielectric layer 170. In example embodiments, each of the internal electrodes 175 may include a precious metal such as gold, silver, platinum, palladium, etc., a high melting point metal such as tungsten, molybdenum, nickel, copper, etc., or a metal oxide such as rubidium oxide, tin oxide, etc.

The first and second electrodes 182 and 184 may be arranged, for example, on the opposite ends of the dielectric layer 170, particularly, on the first and second lateral surfaces of the rectangular parallelepiped shape. The first external electrode 182 may be electrically connected to the first internal electrodes 175a that are exposed at the first surface of the dielectric layer 170, and the second external electrode 184 may be electrically connected to the second internal electrodes 175b that are exposed at the second surface of the dielectric layer 170. In example embodiments, the first and second external electrodes 182 and 184 may include a metal such as copper, palladium, etc.

The first and second external electrodes 182 and 184 may be formed on the respective third pads 134 of a pair of adjacent third pads 134.

A first molding member 200 may also be provided. The first molding member 200 may, for example, include an insulating material such as an epoxy molding compound (EMC) or the like.

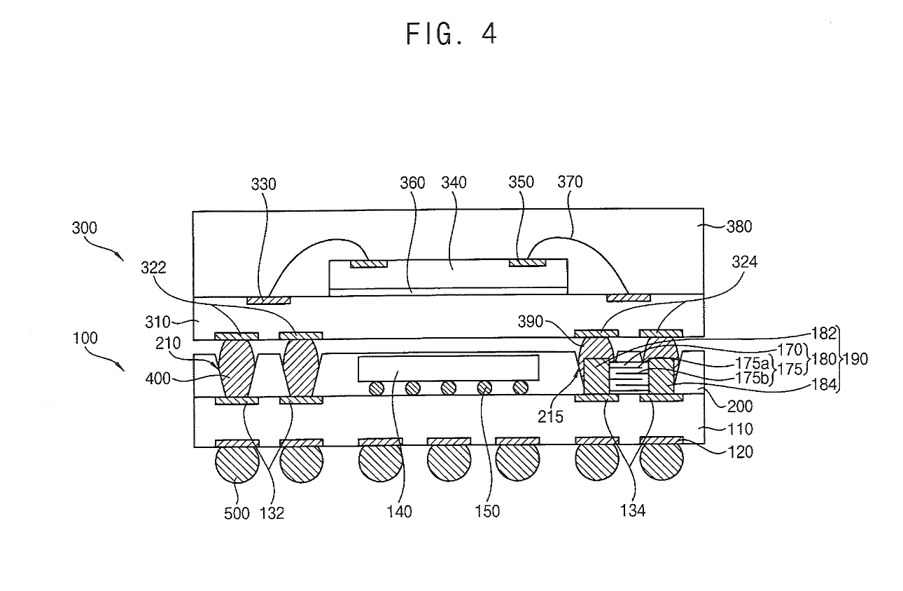

The first molding member 200 may be formed on the first package substrate 110 and may cover at least a portion of the first semiconductor chip 140 and, in some embodiments, may also cover a portion of the multilayer capacitor 190. As shown in FIG. 1, in example embodiments, the first molding member 200 may cover a sidewall and a bottom surface of the first semiconductor chip 140, and thus a top surface of the first semiconductor chip 140 may remain exposed. In other embodiments, the first molding member 200 may cover the top surface as well as the sidewall and the bottom surface of the first semiconductor chip 140, which is illustrated in the example embodiment of FIG. 4. For the convenience of explanation, hereinafter, only the case in which the top surface of the first semiconductor chip 140 is exposed will be discussed.

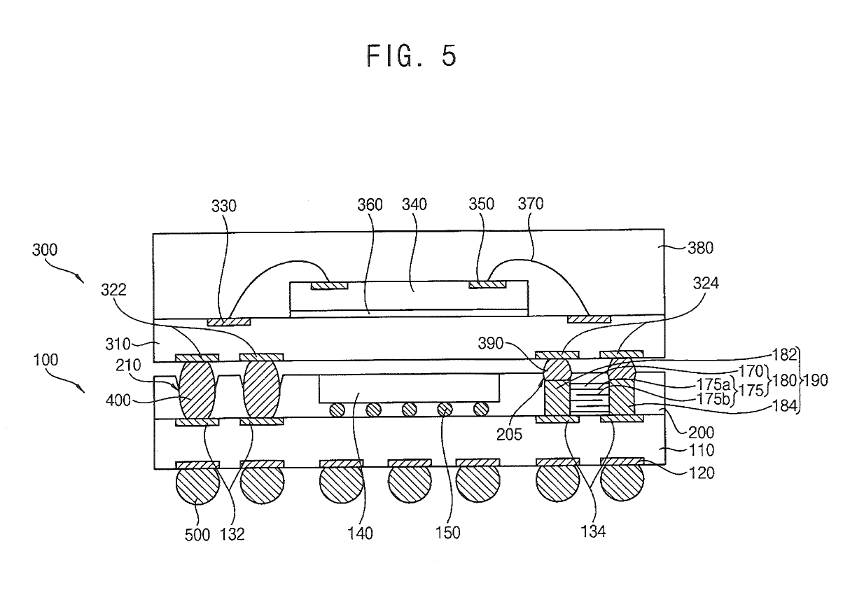

The first molding member 200 may have first openings 210 that expose top surfaces of the second pads 132. The first molding member 200 may further have second openings 215 that expose an upper portion of the multilayer capacitor 190. As shown in the example embodiment of FIG. 1, the second opening 215 may expose top surfaces of the first and second external electrodes 182 and 184 of the multilayer capacitor 190 and may further expose upper outer sidewalls of the first and second external electrodes 182 and 184. In the example embodiment of FIG. 5, the second opening 215 exposes only the top surfaces of the first and second external electrodes 182 and 184 of the multilayer capacitor 190. For the convenience of description, hereinafter, only the case in which the second opening 215 exposes the top surfaces and the upper outer sidewalls of the first and second external electrodes 182 and 184 of the multilayer capacitor 190 will be explained.

The second opening(s) 215 may not completely expose a top surface of the capacitor body 180, and the first molding member 200 may cover at least a portion of the top surface of the capacitor body 180. Thus, the top surface of the capacitor body 180 between the first and second external electrodes 182 and 184 may be at least partially covered by the first molding member 200. This may increase the insulation property between the first and second external electrodes 182 and 184.

The top surfaces of the second pads 132 that are exposed by the first openings 210 may be in contact with the fourth conductive bumps 400, and the upper portion of the multilayer capacitor 190 that is exposed by the second opening 215 may be in contact with the third conductive bumps 390. In example embodiments, the third conductive bumps 390 may cover top surfaces of the first and second external electrodes 182 and 184 that are exposed by the second opening 215 and may also cover upper outer sidewalls thereof (refer to FIG. 1). Thus, the multilayer capacitor 190 may be covered by the first molding member 200 and the third conductive bumps 390, so that the multilayer capacitor 190 may not be deteriorated by environmental changes such as temperature and/or pressure changes, and physical damages thereto may be reduced or prevented.

In example embodiments, the third and fourth conductive bumps 390 and 400 may at least partially fill the second and first openings 215 and 210, respectively, in the first molding member 200. Moreover, portions of the third and fourth conductive bumps 390 and 400 may protrude above a top surface of the first molding member 200. Thus, the third and fourth conductive bumps 390 and 400 may have top surfaces that are higher above the first packaging substrate 110 than is the top surface of the first semiconductor chip 140. As shown in FIG. 4, when the top surface of the first semiconductor chip 140 is covered by the first molding member 200, the first semiconductor chip 140 may be insulated from the second semiconductor package 300, and thus in such embodiments the third and fourth conductive bumps 390 and 400 may have top surfaces that are substantially coplanar with the top surface of the first molding member 200, and the top surface of the first molding member 200 may be in contact with a bottom surface of the second semiconductor package 300.

The multilayer capacitor 190 may be interposed between the third conductive bumps 390 and the third pads 134, and thus the vertical height of the third conductive bumps may be smaller than the vertical height of the fourth conductive bumps 400 which may be in direct contact with the top surface of the second pads 132. The third and fourth conductive bumps 390 and 400 may comprise, for example, solder bumps.

The second semiconductor package 300 may include a second package substrate 310, a second semiconductor chip 340 and a second molding member 380.

The second package substrate 310 may, for example, be a PCB, and may have fourth, fifth and sixth pads 322, 324 and 330. The second package substrate 310 may further include various wirings (not shown) which may be electrically connected to the fourth to sixth pads 322, 324 and 330.

In example embodiments, a plurality of fourth pads 322 and a plurality of fifth pads 324 may be formed at lower portions of the second package substrate 310, and bottom surfaces of the fourth and fifth pads 322 and 324 may be exposed. The fourth and fifth pads 322 and 324 may be formed at positions vertically corresponding to, (i.e., which overlap) the second and third pads 132 and 134, respectively, of the first package substrate 110, and may be in contact with the fourth and third conductive bumps 400 and 390, respectively. In example embodiments, a plurality of sixth pads 330 may be formed at a top surface of the second package substrate 310, and top surfaces of the sixth pads 330 may be exposed. The fourth to sixth pads 322, 324 and 330 may include a conductive material, e.g., a metal.

The first and second semiconductor packages 100 and 300 may be electrically connected to each other via the second pads 132 at the upper portions of the first package substrate 110, the fourth conductive bumps 400 on the second pads 132, and the fourth pads 322 at the lower portion of the second package substrate 310. Further, the first and second semiconductor package 100 and 300 may be electrically connected to each other via the third pads 134 at the upper portions of the first package substrate 110, the multilayer capacitor 190 on the third pads 134, the third conductive bumps 390, and the fifth pads 324 at the lower portion of the second package substrate 310.

The second semiconductor chip 340 may be mounted on the second package substrate 310. For example, the second semiconductor chip 340 may be mounted on a central top surface of the second package substrate 310. In example embodiments, the second semiconductor chip 340 may be attached to the top surface of the second package substrate 310 using an adhesive layer 360. Alternatively, the second semiconductor chips 340 may be attached to the top surface of the second package substrate 310 using conductive bumps (not shown) such as solder balls.

The second semiconductor chip 340 may include one or more bonding pads 350. The bonding pads 350 may be provided, for example, at an upper portion of the second semiconductor chip 340. In example embodiments, a plurality of bonding pads 350 may be formed, and top surfaces of the bonding pads 350 may be exposed. The bonding pads 350 may include a conductive material, e.g., a metal.

The bonding pads 350 of the second semiconductor chip 340 may be electrically connected to respective ones of the sixth pads 330 via a plurality of conductive wires 370. In some embodiments, the bonding pads 350 and conductive wires 370 may be omitted such as, for example, embodiments in which the second semiconductor chip 340 is attached to the second package substrate 310 by conductive bumps.

The second semiconductor chip 340 may include, e.g., a memory chip.

The second molding member 380, for example, may include an insulating material such as EMC, etc. The second molding member 380 may be formed on the second package substrate 310, and may seal the second semiconductor chip 340, the adhesive layer 360 and the conductive wires 370, which may protect these structures from the external environment.

FIG. 1 depicts an embodiment in which the second semiconductor package 300 only has one second semiconductor chip 340. However, the present inventive concept is not limited thereto. Thus, the second semiconductor package 300 may include a plurality of sequentially stacked semiconductor chips 340. Also, in FIG. 1, the case in which the stacked package has only two semiconductor packages 100 and 300 is shown. However, the present inventive concept is not limited thereto. Thus, the stacked semiconductor package may include more than two sequentially stacked semiconductor packages.

Fifth conductive bumps 500 may be formed on the first pads 120 which may be formed at the lower portions of the first package substrate 110, and the first package substrate 110 may be electrically connected to a main board (not shown) or other substrate or surface via the fifth conductive bumps 500.

In accordance with example embodiments, the first semiconductor package 100 and the second semiconductor package 300 may be electrically connected to each other via the multilayer capacitor 190 and the third conductive bumps 390 and by the fourth conductive bumps 400. Thus, signal characteristics in the first semiconductor package 100 or in the second semiconductor package 300 or between the first and second semiconductor packages 100 and 300 may be improved.

Various wirings on the semiconductor packages 100 and 300 may serve as inductors, thereby degrading the signal characteristics such as by causing increased impedance and/or signal overshoot at high frequencies. The multilayer capacitor 190 may improve the signal characteristics. Additionally, the multilayer capacitor 190 may serve as a decoupling capacitor and a low pass filter, thereby reducing noise.

The multilayer capacitor 190 may be formed on the third pads 134 of the first package substrate 110. As a result, the third conductive bumps 390 may be shorter in the vertical direction as compared to the fourth conductive bumps 400 that are formed on the second pads 132. Thus, the multilayer capacitor 190 may be formed in a space that otherwise would have been occupied by the fourth conductive bumps 400, and thus reduced or even no extra space may be required for the multilayer capacitor 190. Consequently, according to certain embodiments of the present invention it may be advantageous to include the multilayer capacitor 190 in the stacked package rather than on the main board which is electrically connected to the first semiconductor package 100 via the fifth conductive bumps 500. In particular, locating the multilayer capacitor 190 in the stacked package may facilitate increased integration and may also position the multilayer capacitor in a location where its effects on signal conditioning may be greater.

Furthermore, the multilayer capacitor 190 may be protected by the first molding member 200, and thus the deterioration of the characteristics thereof and the physical damage thereto may be reduced or prevented.

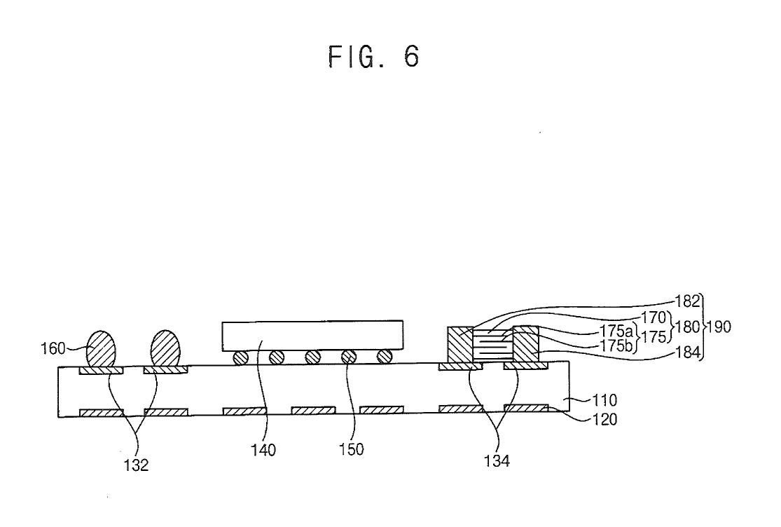

FIGS. 6 to 11 are cross-sectional views illustrating stages of a method of manufacturing a stacked package in accordance with example embodiments.

Referring to FIG. 6, a first semiconductor chip 140 may be mounted on a first package substrate 110. A second conductive bump 160 and a multilayer capacitor 190 may be attached to a top surface of the first package substrate 110.

The first package substrate 110 may be, for example, a PCB, and may have first to third pads 120, 132 and 134. In example embodiments, a plurality of first pads 120 may be formed at lower portions of the first package substrate 110, and bottom surfaces of the first pads 120 may be exposed so that they can be used to electrically connect the first package substrate to an underlying structure (e.g., a main board) in a later process. A plurality of second and third pads 132 and 134 may be formed on upper portions of the first package substrate 110. The second and third pads 132 and 134 may be spaced apart from the first semiconductor chip 140, and top surfaces of the second and third pads 132 and 134 may likewise be exposed. The second and third pads 132 and 134 may be arranged at regular intervals. Two of the plurality of third pads 134, which may be adjacent to each other, may form a first pair of third pads 134. The first to third pads 120, 132 and 134 may include a conductive material such as, for example, a metal.

The first semiconductor chip 140 may be mounted on the first package substrate 110 by a plurality of first conductive bumps 150. For example, after the first conductive bumps 150 including solder balls are arranged on a central top surface of the first package substrate 110, the first semiconductor chip 140 may be arranged over the central top surface of the first package substrate 110 so that a bottom surface of the first semiconductor chip 140 may contact the first conductive bumps 150. A reflow process may be performed on the first conductive bumps 150 so that the first conductive bumps 150 may be attached to the bottom surface of the first semiconductor chip 140 and the top surface of the first package substrate 110. A plurality of conductive pads (not shown) may be provided on the upper surface of the first package substrate and on the lower surface of the first semiconductor chip 140 that electrically connect the first semiconductor chip 140 to the first package substrate 110.

In some embodiments, a plurality of second conductive bumps 160 that include, for example, solder, may be arranged on the second pads 132, respectively, and may be attached to top surfaces of the second pads 132, respectively, through a reflow process.

A multilayer capacitor 190 may be provided that includes a capacitor body 180, and first and second external electrodes 182 and 184. The first and second external electrodes 182 and 184 may be attached to top surfaces of the first pair of third pads 134. In one example embodiment, solder paste may be coated on the top surfaces of the third pads 134, and the first and second external electrodes 182 and 184 may be attached to the top surfaces of the third pads 134.

The capacitor body 180 may include a dielectric layer 170 and a plurality of stacked internal electrodes 175. The dielectric layer 170 may, for example, have a rectangular parallelepiped shape which may have four lateral surfaces that are substantially perpendicular to the top surface of the first package substrate 110, and two of the lateral surfaces, e.g., first and second lateral surfaces may be opposite to each other, and the other two of the lateral surfaces, e.g., third and fourth lateral surfaces may be opposite to each other and substantially perpendicular to the first and second lateral surfaces. Each of the internal electrodes 175 may, for example, have a flat plate shape that is substantially parallel to the top surface of the first package substrate 110. In example embodiments, the internal electrodes 175 may include a first internal electrode 175a and a second internal electrode 175b. The first internal electrode 175a may have one end portion that is exposed at the first surface and the other end portion that is formed at an inside of the dielectric layer 170. The second internal electrode 175b may have one side that is exposed at the second surface and the other end portion that is formed at the inside of the dielectric layer 170. The first and second internal electrodes 175a and 175b may be alternately stacked in the dielectric layer 170 along a direction that is substantially perpendicular to a top surface of the first package substrate 110. The first and second external electrodes 182 and 184 may be arranged at both ends of the dielectric layer 170, respectively, specifically, at the first and second lateral surfaces of the rectangular parallelepiped shape. Thus, the first external electrode 182 may be electrically connected to the first internal electrodes 175a which may be exposed at the first surface of the dielectric layer 170, and the second external electrode 184 may be electrically connected to the second internal electrodes 175b which may be exposed at the second surface of the dielectric layer 170.

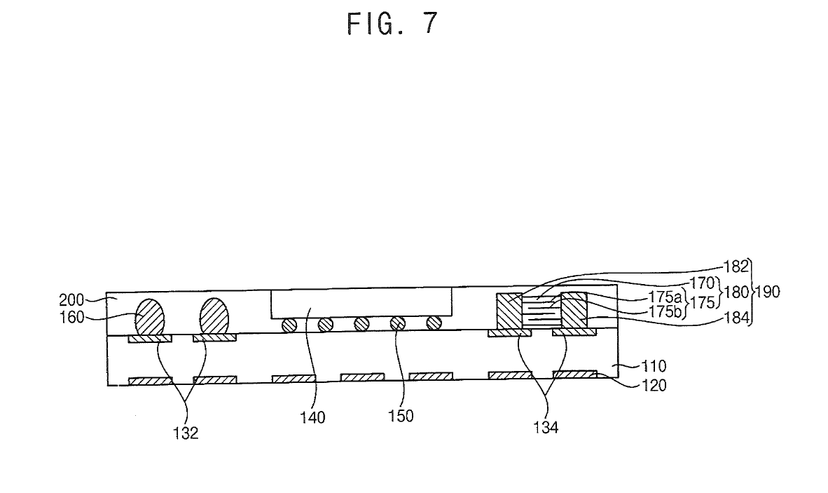

Referring to FIG. 7, a first molding member 200 may be formed on the first package substrate 110 sufficiently to cover the first semiconductor chip 140, the first conductive bumps 150, the second conductive bumps 160 and the multilayer capacitor 190. The first molding member 200 may be planarized until a top surface of the first semiconductor chip 140 is exposed. The first molding member 200 may, for example, be formed using EMC.

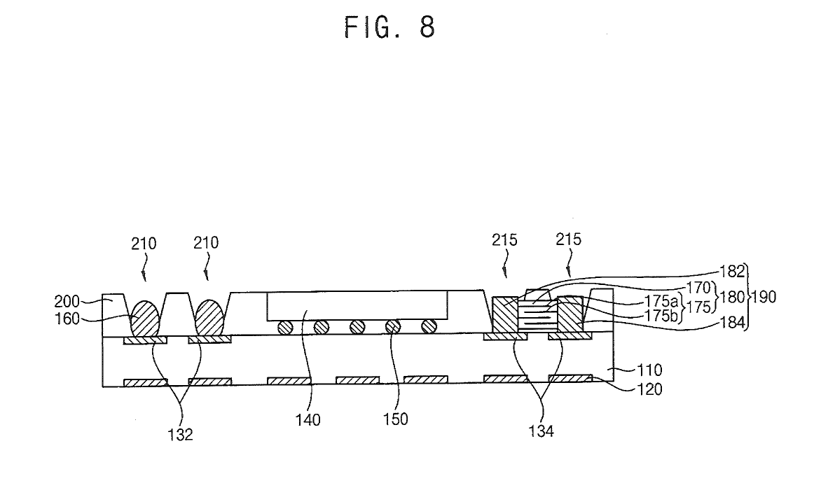

Referring to FIG. 8, the first molding member 200 may be partially removed to form first openings 210 that expose top surfaces of the second pads 132 and second openings 215 that expose at least portions of the top surface of the multilayer capacitor 190.

In example embodiments, the first and second openings 210 and 215 may be formed with a laser drill or a mechanical drill.

In example embodiments, the second openings 215 may be formed to expose at least top surfaces of the first and second external electrodes 182 and 184 of the multilayer capacitor 190, and to further expose upper outer sidewalls of the first and second external electrodes 182 and 184. However, the second openings 215 may not completely expose the top surface of the capacitor body 180 so that at least a portion of the top surface of the capacitor body 180 is covered by the first molding member 200.

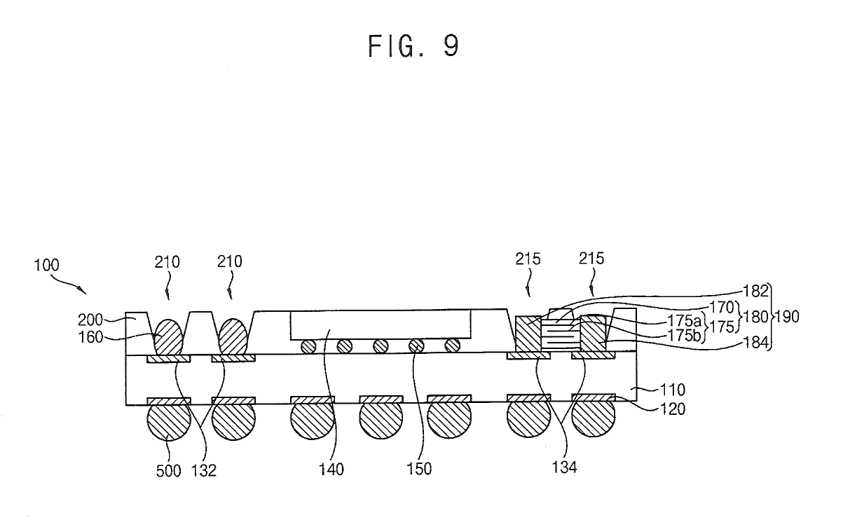

Referring to FIG. 9, fifth conductive bumps 500 may be attached to a bottom surface of the first package substrate 110, and a sawing process may be performed to divide the first package substrate 110 into plurality of separate pieces, so that a plurality of first semiconductor packages 100 are formed. Hereinafter, only one of the plurality of first semiconductor packages 100 will be discussed.

For example, the fifth conductive bumps 500 including solder may be arranged on the first pads 120, respectively, and a reflow process may be performed on the fifth conductive bumps 500 to attach the fifth conductive bumps 500 to their associated first pads 120. After a temporary adhesive (not shown) which may cover the fifth conductive bumps 500 is coated on a bottom surface of the first package substrate 110, a carrier substrate (not shown) may be attached to the temporary adhesive, and the first package substrate 110 may be divided by a sawing process.

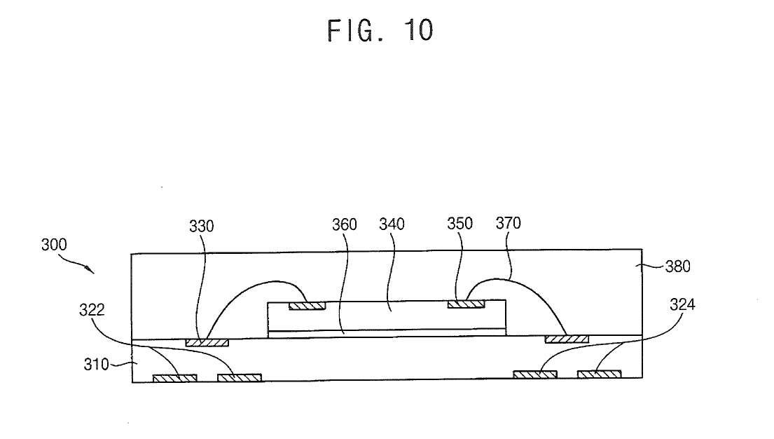

Referring to FIG. 10, a second semiconductor chip 340 may be mounted on a second package substrate 310. The second semiconductor chip 340 may be electrically connected to the second package substrate 310 via one or more conductive wires 370. A second molding member 380 may be formed on the second package substrate 310 that covers, seals and/or protects the second semiconductor chip 340 and the conductive wires 370, thereby completing formation of a second semiconductor package 300.

The second package substrate 310 may be, for example, a PCB, and may have fourth to sixth pads 322, 324 and 330. In example embodiments, a plurality of fourth and fifth pads 322 and 324 may be formed at lower portions of the second package substrate 310, and bottom surfaces of the fourth and fifth pads 322 and 324 may be exposed. In example embodiments, a plurality of sixth pads 330 may be formed at upper portions of the second package substrate 310, and top surfaces of the sixth pads 330 may be exposed. The fourth to sixth pads 322, 324 and 330 may include a conductive material such as a metal.

An adhesive layer 360 may be formed on a central top surface of the second package substrate 310, and a bottom surface of the second semiconductor chips 340 may be in contact with the adhesive layer 360, and the second semiconductor chip 340 may be mounted on the second package substrate 310. The second semiconductor chip 340 may include a plurality of bonding pads 350 at upper portions thereof. Top surfaces of the bonding pads 350 may be exposed externally from the second semiconductor chip 340. The bonding pads 350 may include a conductive material such as a metal.

The conductive wires 370 may be arranged to connect the bonding pads 350 of the second semiconductor chip 340 with respective ones of the sixth pads 330 of the second package substrate 310.

The second molding member 380 may be formed using an insulating material such as EMC.

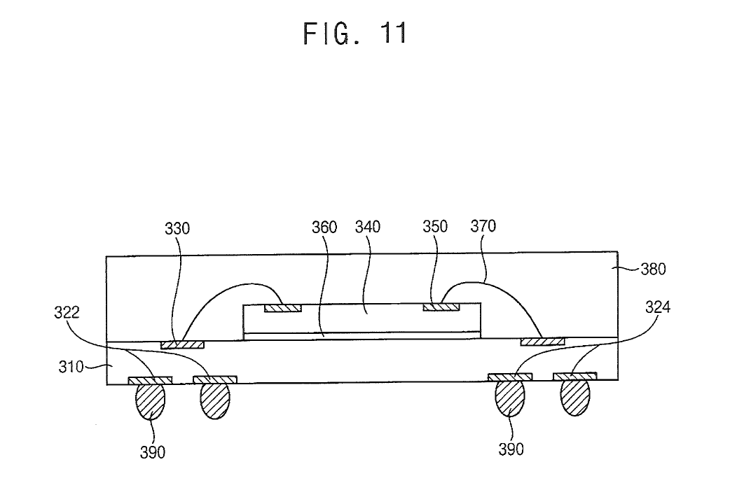

Referring to FIG. 11, third conductive bumps 390 may be attached on a bottom surface of the second semiconductor package 300. The third conductive bumps 390 may include solder and may be arranged on the fourth and fifth pads 322 and 324, respectively, of the second package substrate 310, and may be attached to the fourth and fifth pads 322 and 324 by a reflow process.

Referring to FIG. 1 again, the second semiconductor package 300 may be joined to the first semiconductor package 100 to manufacture the stacked package.

In particular, the third conductive bumps 390 that are formed on the bottom surface of the second package substrate 310 may be placed in contact with top surfaces of the multilayer capacitor 190 and the second conductive bumps 160 that are formed on the top surface of the first package substrate 110. A reflow process may then be performed that joins some of the third conductive bumps 390 to the electrodes 182, 184 of the multilayer capacitor 190 and that joins other of the third conductive bumps 390 to the second conductive bumps 160 to form fourth conductive bumps 400.

The carrier substrate and the temporary adhesive attached to the bottom surface of the first package substrate 110 may be removed, and fifth conductive bumps 500 may be mounted on the main board (not shown).

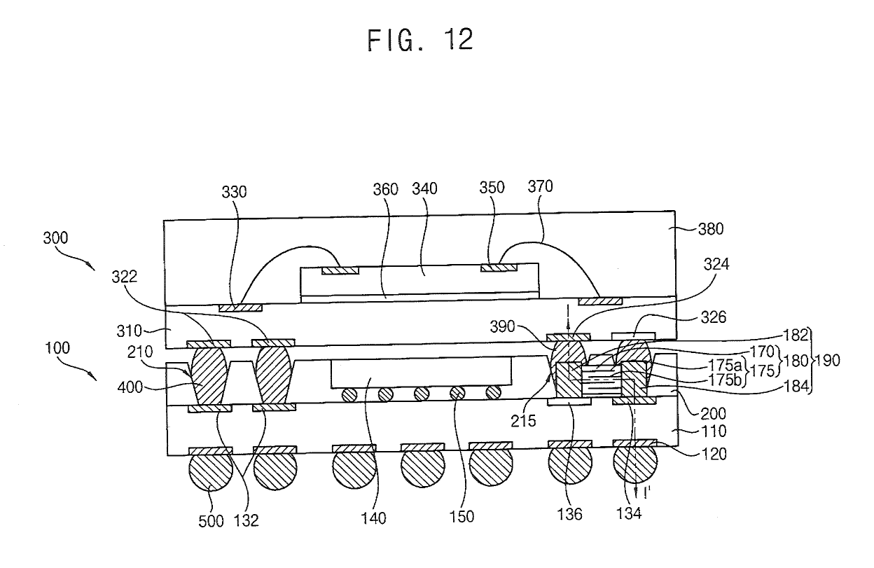

FIG. 12 is a cross-sectional view illustrating a stacked package in accordance with example embodiments. The stacked package may be substantially the same as or similar to the stacked package of FIGS. 1 and 2 except for the pads. Thus, like reference numerals refer to like elements, and detailed descriptions thereon are omitted herein.

Referring to FIG. 12, the stacked package may include a first semiconductor package 100, a second semiconductor package 300, and third and fourth conductive bumps 390 and 400.

The first semiconductor package 100 may include a first package substrate 110, a first semiconductor chip 140, a multilayer capacitor 190 and a first molding member 200.

The first package substrate 110 may include first to third pads 120, 132 and 134, and a seventh pad 136. In example embodiments, the second, third and seventh pads 132, 134 and 136 may be formed at upper portions of the first package substrate 110 and may be spaced apart from the first semiconductor chip 140. Top surfaces of the second, third and seventh pads 132, 134 and 136 may be exposed. The second, third and seventh pads 132, 134 and 136 may be arranged at regular intervals, and the third and seventh pads 134 and 136 may be arranged adjacent each other. That is, one of the third pads 134 of the first pair of third pads 134 in the embodiment of FIGS. 1 and 2 may be replaced by the seventh pad 136 so that the third and seventh pads 134 and 136 in FIG. 12 may be arranged as a pair of pads. The first to third pads 120, 132 and 134 may include a conductive material, e.g., a metal, and the seventh pad(s) 136 may include an insulating material.

The multilayer capacitor 190 may include a capacitor body 180, and first and second external electrodes 182 and 184. The first and second external electrodes 182 and 184 may contact top surfaces of the seventh and third pads 136 and 134, respectively.

The second semiconductor package 300 may include a second package substrate 310, a second semiconductor chip 340 and a second molding member 380.

The second package substrate 310 may include fourth to sixth pads 322, 324 and 330, and an eighth pad 326. In example embodiments, a plurality of fourth pads 322, a plurality of fifth pads 324 and a plurality of eighth pads 326 may be formed at lower portions of the second package substrate 310, and bottom surfaces of the fourth, fifth and eighth pads 322, 324 and 326 may be exposed. The fourth, fifth and eighth pads 322, 324 and 326 may be formed at positions that are vertically aligned (or at least overlapping) the second, seventh and third pads 132, 136 and 134, respectively. Thus, according to the present embodiment one of the fifth pads 324 that is adjacent another of the fifth pads 324 to make a pair of fifth pads 324 in the embodiment of FIGS. 1 and 2 may be replaced by the eighth pad 326 so that the fifth and eighth pads 324 and 326 in FIG. 12 are arranged as a pair of pads.

Thus the fourth pads 322 may contact the fourth conductive bumps 400, and the fifth and eighth pads 324 and 326 may contact the third conductive bumps 390. The fourth to sixth pads 322, 324 and 330 may include a conductive material, e.g., a metal and the eighth pad(s) 326 may include an insulating material.

The first semiconductor package 100 and the second semiconductor package 300 in the stacked package may be electrically connected to each other via the multilayer capacitor 190 and the third conductive bumps 390 as well as the fourth conductive bumps 400. A signal may be transmitted from the second semiconductor package 300 to the first semiconductor package 100 and the main board (not shown) through a line I-I′, and thus the characteristics of signals that are transmitted from the second semiconductor chip 340 to the first semiconductor chip 140 may be improved and transmitted to the main board.

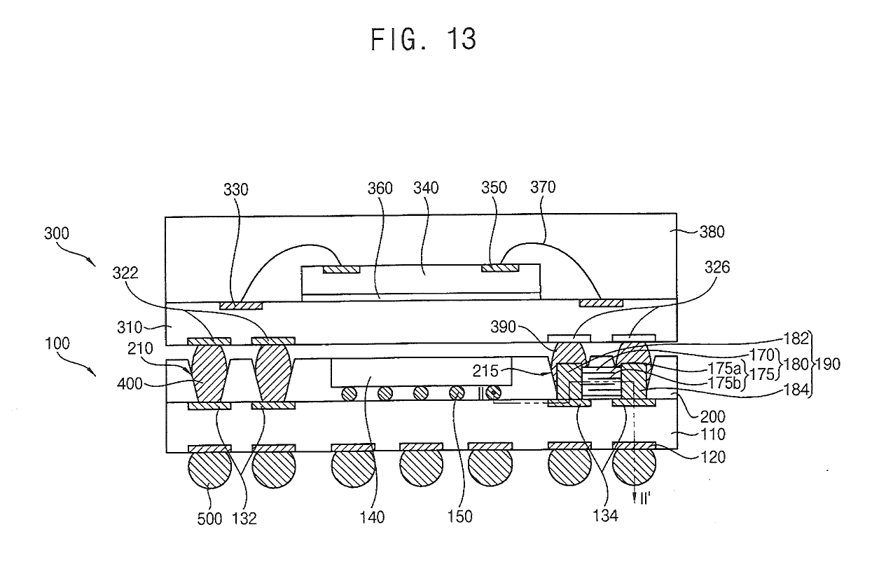

FIG. 13 is a cross-sectional view illustrating a stacked package in accordance with example embodiments. The stacked package may be substantially the same as or similar to that of FIGS. 1 and 2 except for the pads. Thus, like reference numerals refer to like elements, and detailed descriptions thereon are omitted herein.

Referring to FIG. 13, the stacked package may include a first semiconductor package 100, a second semiconductor package 300, and third and fourth conductive bumps 390 and 400.

The first semiconductor package 100 may include a first package substrate 110, a first semiconductor chip 140, a multilayer capacitor 190, and a first molding member 200. The first package substrate 110 may include first to third pads 120, 132 and 134. The multilayer capacitor 190 may include a capacitor body 180, and first and second external electrodes 182 and 184. The first and second external electrodes 182 and 184 may contact top surfaces of the third pads 134.

The second semiconductor package 300 may include a second package substrate 310, a second semiconductor chip 340 and a second molding member 380.

The second package substrate 310 may include fourth and sixth pads 322 and 330 and eighth pads 326. In example embodiments, a plurality of fourth and eighth pads 322 and 326 may be formed at lower portions of the second package substrate 310, and bottom surfaces of the fourth and eighth pads 322 and 326 may be exposed. The fourth and eighth pads 322 and 326 may be vertically aligned with the second and third pads 132 and 134, respectively. That is, the fifth pads 324 in FIGS. 1 and 2 may be replaced by the eighth pads 326 in the embodiment of FIG. 13.

Thus, the fourth pads 322 may contact the fourth conductive bumps 400, and the eighth pads 326 may contact the third conductive bumps 390. The fourth and sixth pads 322 and 330 may include a conductive material, e.g., a metal, and the eighth pads 326 may include an insulating material.

The first semiconductor package 100 and the second semiconductor package 300 in the stacked package may be electrically connected to each other via the fourth conductive bumps 400. A signal may be transmitted from the first semiconductor package 100 to the main board (not shown) through a line and the characteristics of the signal transmitted from the first semiconductor chip 140 to the main board may be improved.

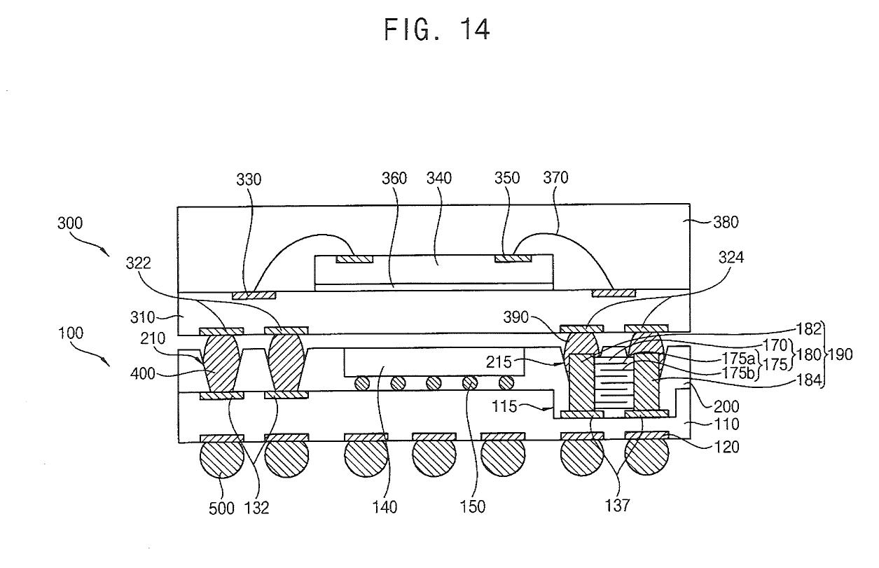

FIG. 14 is a cross-sectional view illustrating a stacked package in accordance with example embodiments. The stacked package may be substantially the same as or similar to that of FIGS. 1 and 2 except for the first package substrate. Thus, like reference numerals refer to like elements, and detailed descriptions thereon are omitted herein.

Referring to FIG. 14, the stacked package may include a first semiconductor package 100, a second semiconductor package 300, and third and fourth conductive bumps 390 and 400.

The first semiconductor package 100 may include a first package substrate 110, a first semiconductor chip 140, a multilayer capacitor 190 and a first molding member 200.

A recess 115 may be provided in the first package substrate 110 to form a recessed region in the first package substrate. The recess 115 may be spaced apart from a portion of the first package substrate 110 on which the first semiconductor chip 140 is mounted.

The first package substrate 110 may include first pads 120 at lower portions thereof and second pads 132 at upper portions thereof where the recess 115 is not formed, and ninth pads 137 may be formed on the recess 115. In example embodiments, bottom surfaces of the first pads 120 may be exposed externally from a bottom surface of the first package substrate 110, top surfaces of the second pads 132 may be exposed externally from a top surface of the first package substrate 110, and the ninth pads 137 may be exposed externally from the recess 115 on the first package substrate 110. In example embodiments, the ninth pads 137 may have top surfaces lower than a top surface of the first package substrate 110 where the recess 115 is not formed. The first, second and ninth pads 120, 132 and 137 may include a conductive material, e.g., a metal.

The multilayer capacitor 190 may include a capacitor body 180, and first and second external electrodes 182 and 184. The capacitor body 180 may include a dielectric layer 170 and a plurality of internal electrodes 175 stacked therein. The multilayer capacitor 190 in FIG. 14 may have a greater number of stacked internal electrodes 175 as compared to the multilayer capacitor 190 in FIG. 1, and thus may have a relatively higher electric capacity and an increased thickness in the vertical direction. Even though a vertical height of the multilayer capacitor 190 may be greater than a vertical height of the fourth conductive bumps 400, a top surface of the multilayer capacitor 190 may be lowered by the recess 115 on the first package substrate 110 such that the first and second semiconductor packages 100 and 300 may be stacked easily.

The first molding member 200 may be formed on the first package substrate 110 to cover at least a portion of the first semiconductor chip 140, a portion of the multilayer capacitor 190, and the ninth pads 137.

The second semiconductor package 300 may include a second package substrate 310, a second semiconductor chip 340 and a second molding member 380.

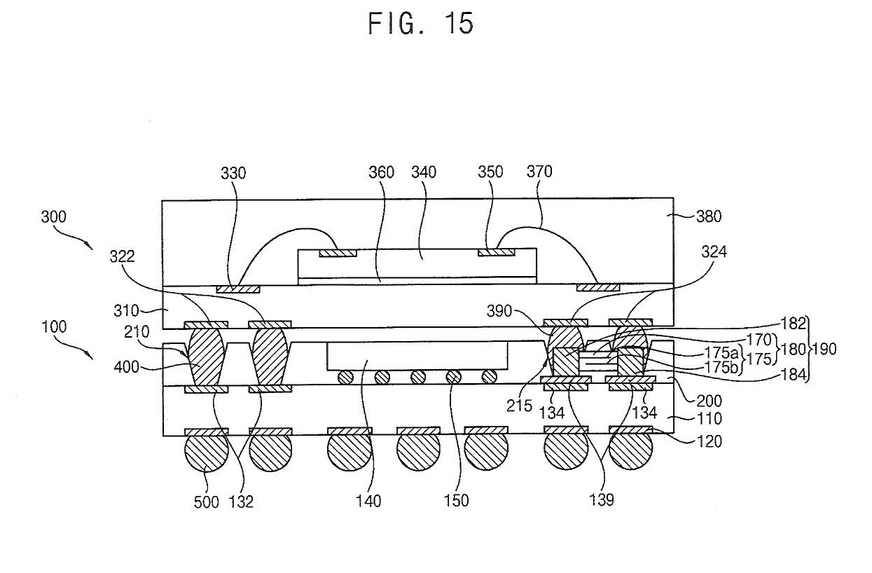

FIG. 15 is a cross-sectional view illustrating a stacked package in accordance with example embodiments. The stacked package may be substantially the same as or similar to that of FIGS. 1 and 2 except for the pads. Thus, like reference numerals refer to like elements, and detailed descriptions thereon are omitted herein.

Referring to FIG. 15, the stacked package may include a first semiconductor package 100, a second semiconductor package 300, and third and fourth conductive bumps 390 and 400.

The first semiconductor package 100 may include a first package substrate 110, a first semiconductor chip 140, a multilayer capacitor 190 and a first molding member 200.

The first package substrate 110 may include first to third pads 120, 132 and 134, and tenth pads 139 may be formed at the third pads 134. The first to third pads 120, 132 and 134 and the tenth pads 139 may include a conductive material, e.g., a metal.

The multilayer capacitor 190 may include a capacitor body 180, and first and second external electrodes 182 and 184. The capacitor body 180 may include a dielectric layer 170 and a plurality of internal electrodes 175 stacked therein. The multilayer capacitor 190 in FIG. 14 may have fewer internal electrodes 175 than the multilayer capacitor 190 in FIG. 1, and thus may have a relatively lower electric capacity and may not extend as far upward in the vertical direction. Even though a vertical height of the multilayer capacitor 190 and one of the third conductive bumps 390 stacked thereon of FIG. 15 may be less than the vertical height of the fourth conductive bumps 400, the top surface of the multilayer capacitor 190 may be at the same level as the top surfaces of the fourth conductive bumps 400 due to the inclusion of the tenth pads 139 on the first package substrate 110, such that the first and second semiconductor packages 100 and 300 may be stacked easily.

The first molding member 200 may be formed on the first package substrate 110 to cover at least a portion of the first semiconductor chip 140, a portion of the multilayer capacitor 190, and the tenth pads 139.

The second semiconductor package 300 may include a second package substrate 310, a second semiconductor chip 340 and a second molding member 380.

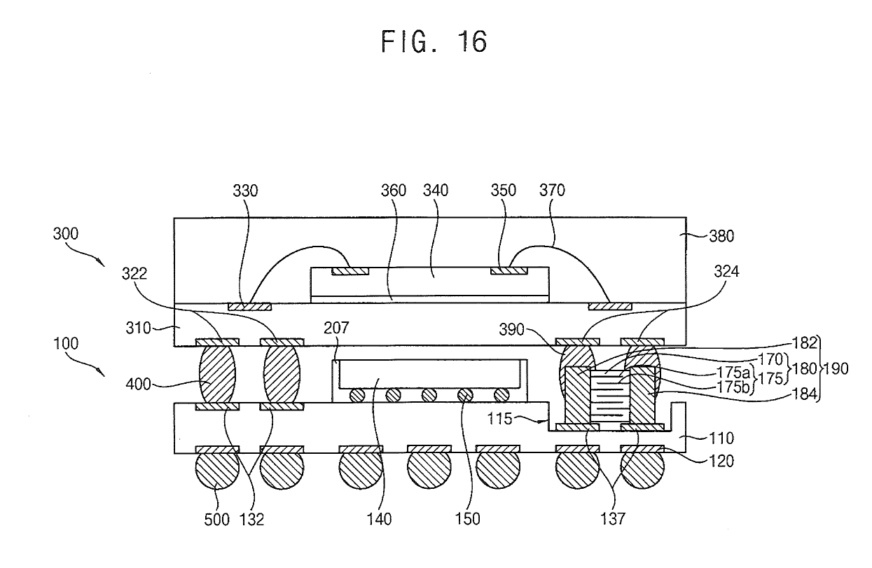

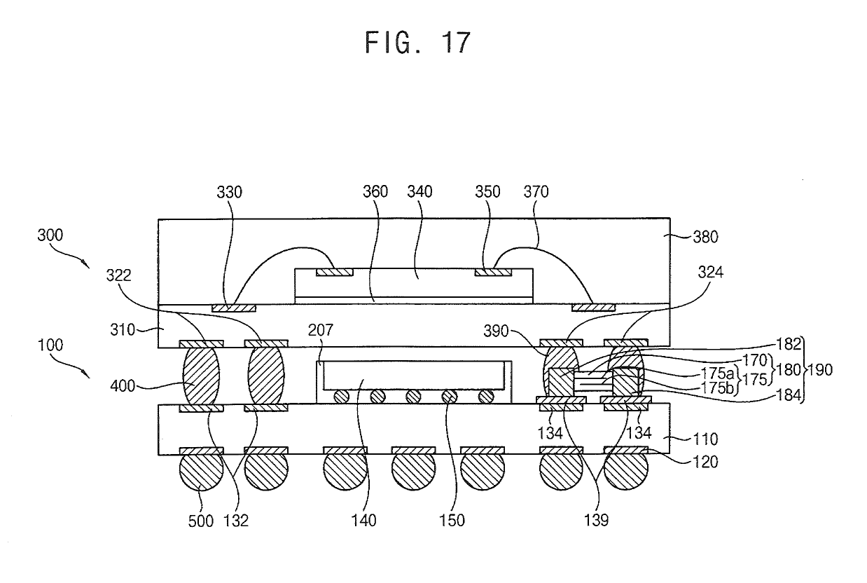

FIGS. 16 and 17 are cross-sectional views illustrating a stacked package in accordance with example embodiments. The stacked package may be substantially the same as or similar to that of FIGS. 1 and 2 except for the molding member. Thus, like reference numerals refer to like elements, and detailed descriptions thereon are omitted herein.

Referring to FIGS. 16 and 17, the stacked package may include a first semiconductor package 100, a second semiconductor package 300, and third and fourth conductive bumps 390 and 400. The first semiconductor package 100 may include a first package substrate 110, a first semiconductor chip 140, a multilayer capacitor 190 and a third molding member 207.

The third molding member 207 may be formed on the first package substrate 110 to cover at least a portion of the first semiconductor chip 140. In example embodiments, the third molding member 207 may cover a sidewall and a bottom surface of the first semiconductor chip 140. However, the third molding member 207 may not cover the multilayer capacitor 190, and may cover neither the ninth pads 137 (in the embodiment of FIG. 16) nor the tenth pads 139 (in the embodiment of FIG. 17).

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A stacked package, comprising:
a first package substrate having a first semiconductor chip thereon;
a multilayer capacitor on the first package substrate, the multilayer capacitor being spaced apart from the first semiconductor chip;
a molding member on the first package substrate, the molding member covering at least a portion of the first semiconductor chip; and
a second package substrate arranged over the first package substrate and electrically connected thereto.

2. The stacked package of claim 1, wherein the first package substrate includes a plurality of first pads and a plurality of second pads at upper portions thereof and first conductive bumps on the plurality of first pads.

3. The stacked package of claim 2, wherein the multilayer capacitor includes first and second external electrodes that are electrically connected to respective first and second of the plurality of second pads.

4. The stacked package of claim 3, further comprising second conductive bumps on at least upper surfaces of the first and second external electrodes.

5. The stacked package of claim 4, wherein the second conductive bumps are on upper sidewalls of the first and second external electrodes.

6. The stacked package of claim 4, wherein the second package substrate has a second semiconductor chip thereon and third and fourth pads at lower portions thereof, and wherein the first conductive bumps are electrically connected to the third pads, and the second conductive bumps are electrically connected to the fourth pads.

7. The stacked package of claim 6, wherein the first to the fourth pads have a conductive material.

8. The stacked package of claim 6, wherein some of the second pads include a conductive material and the others of the second pads include an insulating material, and some of the fourth pads include a conductive material and the others of the fourth pads include an insulating material.

9. The stacked package of claim 6, wherein all of the second pads include a conductive material and all of the fourth pads include an insulating material.

10. The stacked package of claim 2, further comprising a plurality of fifth pads between the multilayer capacitor and the second pads, respectively.

11. The stacked package of claim 1, wherein the first package substrate includes a recessed region and first pads at upper portions of the first package substrate and second pads on the recessed region, and wherein first conductive bumps are formed on the first pads, and the multilayer capacitor is formed on the second pads.

12. A stacked package, comprising:
a first semiconductor package, including:
a first package substrate that has a first semiconductor chip on a central top surface thereof;
a plurality of conductive bumps on the first package substrate, the conductive pumps being arranged around the first semiconductor chip; and
at least one multilayer capacitor on the first package substrate adjacent the conductive bumps, wherein a distance between the at least one multilayer capacitor and the conductive bumps adjacent thereto is substantially the same as a distance between the conductive bumps; and
a second package substrate on the first package substrate, the second package substrate being electrically connected to the first package substrate via the conductive bumps and the multilayer capacitor.

13. A stacked package, comprising:
a first package substrate having a major surface that defines a horizontal plane;
first pads on an upper portion of the first package substrate;
a multilayer capacitor on the first pads;
a first semiconductor chip on the first package substrate;
a second package substrate on the first semiconductor package;
a second semiconductor chip on the second package substrate; and
conductive bumps between the first package substrate and the second package substrate that are vertically aligned with the multilayer capacitor.

14. The stacked package of claim 13, further comprising second pads on a lower portion of the second package substrate that are vertically aligned with the multilayer capacitor.

15. The stacked package of claim 14, wherein the conductive bumps comprise first conductive bumps, the stacked package further comprising:
third pads on the upper portion of the first package substrate;
fourth pads on the lower portion of the second package substrate; and
second conductive bumps that electrically connect respective ones of the third pads to respective ones of the fourth pads.

16. The stacked package of claim 15, further comprising a molding member on the first package substrate that covers at least a portion of the first semiconductor chip, wherein the first and second conductive bumps penetrate the molding member.

17. The stacked package of claim 14, wherein at least one of the first pads, at least one of the second pads, at least one of the second the conductive bumps and the multilayer capacitor provide a signal path between the first and second package substrates.

18. The stacked package of claim 15, wherein the first package substrate includes a recessed region, and wherein the first pads are within the recessed region.

19. The stacked package of claim 15, wherein the multilayer capacitor has first and second external electrodes, and wherein one of the first pads, the first external electrode, one of the first conductive bumps and one of the second pads are vertically aligned, and wherein another of the first pads, the second external electrode, another of the first conductive bumps and another of the second pads are vertically aligned.

20. The stacked package of claim 14, wherein at least one of the first pads or one of the second pads that are vertically aligned with the multilayer capacitor comprise an insulating material.
